(19) United States
(12) Patent Application Publication
(10) Pub. No.: US 2026/0002965 A1
(43) Pub. Date: Jan. 1, 2026

(54) AUTOSET FEATURE AS PART OF BUS CONFIGURATION TO AUTOMATICALLY DETECT AND SET SERIAL BUS PARAMETERS

(71) Applicant: Tektronix, Inc., Beaverton, OR (US)

(72) Inventors: Archana I. Akkalakot, Bengaluru (IN); Alka Kumari, Bengaluru (IN); Sushree Sangita Dash, Bengaluru (IN)

(21) Appl. No.: 19/242,474

(22) Filed: Jun. 18, 2025

(30) Foreign Application Priority Data
Jun. 28, 2024 (IN) 202421049667

(51) Int. Cl. G01R 13/02

(52) U.S. Cl. CPC G01R 13/0218

(57) ABSTRACT

A test and measurement instrument includes one or more ports to connect one or more devices under test (DUTs) through a bus to one or more channels of the test and measurement instrument, a user interface to allow a user to provide user inputs to the test and measurement instrument, a display to allow a user to view information about the one or more DUTs, one or more processors configured to execute code that causes the one or more processors to: receive a signal from one DUT of the one or more DUTs and convert the signal to a waveform, receive a user input indicating a bus type, use the bus type to identify parameters for autoset detection, autoset one or more parameter values for the bus, decode the waveform using the parameter values to produce decoded results, and display the decoded results on the user interface.

### CROSS-REFERENCE TO RELATED APPLICATIONS

This disclosure claims priority under 35 U.S.C. § 119 to Indian Provisional Patent Application No. 202421049667, titled “AUTO SET FEATURE AS PART OF BUS CONFIGURATION TO AUTOMATICALLY DETECT AND SET SERIAL BUS PARAMETERS,” filed on Jun. 28, 2024, the disclosure of which is incorporated herein by reference in its entirety.

### TECHNICAL FIELD

The present disclosure relates to the field of digital signal processing, more particularly to decoding traffic signals on a communications bus.

### BACKGROUND

Many different test and measurement instruments, such as Mixed-Signal Oscilloscopes (MSO), have protocol decode solutions debug and validate different serial bus standards. These buses need some parameters to decode the input waveforms received by scopes. Some of these parameters include threshold, data rate, input source, and polarity. Threshold is required to digitize the waveform as 1's or 0's depending on the level set. Serial buses that are not clocked, such as CXPI (Clock Extension Peripheral Interface) and NRZ (Non-Return to Zero) need the data rate parameters to digitize the waveform. The input source identifies the channel to which the signal is connected. Polarity is required to know the polarity whether Active High or Active low.

Currently users set all these configuration parameters by studying the signals from the device under test (DUT). Some parameters like threshold and data rate are very difficult to set when the signal is noisy. If these parameters are not set properly, then the decode will be incorrect. User must repeatedly try with different values till one gets proper values to set these parameters to get the decode. This makes a pain point for the user.

### BRIEF DESCRIPTION OF THE DRAWINGS

FIG. 1 shows an embodiment of a test and measurement instrument.

FIG. 2 shows an embodiment of a current user interface.

FIG. 3 shows a user interface with an Autoset feature.

FIG. 4 shows a flow chart of an embodiment of automatically detecting and setting a threshold value.

FIG. 5 shows a flow-chart of an embodiment to automatically detect and set a data rate.

FIG. 6 shows decoded results using automatically detected parameters as a waveform.

### DETAILED DESCRIPTION

The embodiments disclosed herein provide a test and measurement instrument that can perform automatic setting of the parameters of a particular bus. The embodiments detect certain parameters such as voltage threshold(s), data rate, and skew, from the signals on the bus automatically. The instrument then displays these values on a user interface for the user to note and use the values to decode the data on the bus. As used herein, the terms “autoset” and “autosetting” refer to a process in which certain parameter values are automatically detected and set by a test and measurement instrument or other device that can determine the values from traffic on the bus. The term “Autoset” when capitalized refers to the feature or setting on the device or instrument.

The Autoset feature on test and measurement instruments makes use of advanced algorithms and a series of measurements to analyze the incoming waveform. Based on the waveform's characteristics, the oscilloscope then configures itself for the best possible display. Similarly, the AutoSet feature for bus configuration will make use of algorithms to determine setting options such as threshold, rate, skew etc. to give an easy way to determine the input options. The threshold, data rate, and skew comprise some examples of parameters determined and set by Autoset. No limitation to these particular examples is intended nor should it be inferred.

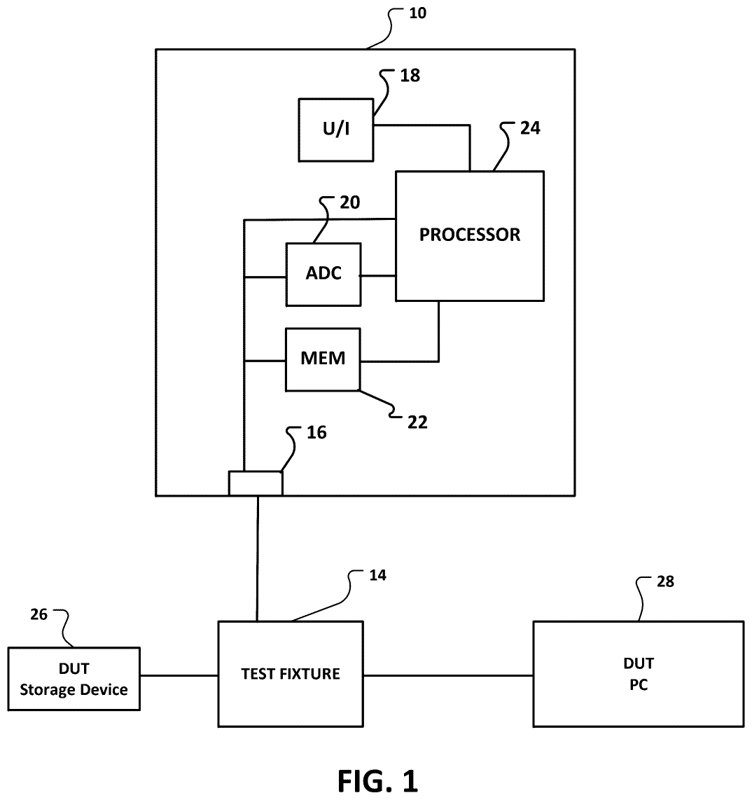

FIG. 1 shows an embodiment of a test and measurement instrument. The test and measurement instrument 10 connects to a text fixture 14 that is in turn connected to one or more DUTs 26 and 28. In one embodiment, the DUT 26 may comprise a storage device, and the DUT 28 may comprise a PC. The connection may involve one or more probes on the test fixture. While these will both be referred to as DUTs, decoding operation applies to whichever of the computing device 28 or the storage device 26 is transmitting the data. The test fixture 14 sends the data through one or more channels 16 on test and measurement instrument 10. In some embodiments, the test fixture 14 may comprise a probe. As discussed above, the embodiments herein will typically only use one probe and one channel of the instrument, but more may be used.

The data from the test fixture 14, if analog, undergoes conversion to digital by one or more analog-to-digital converters (ADC), such as ADC 20. The ADC 20 converts the analog data to digital data for the one or more processors such as processor 24 to operate upon the digital data. If the data received comprises digital data, the digital data bypasses ADC 20. The test and measurement instrument 10 may include a memory 22 to allow the one or more processors 24 to store the digital and analog data and may contain the code to be executed by the one or more processors 24. User interface 18 allows the test and measurement instrument 10 to display information to the user, such as waveforms of the received data, measurements of those waveforms, decoded data, etc., and may include controls such as buttons, knobs, sliders, trackballs, etc., to allow the user to perform operations on the incoming signals, etc.

The test fixture 14 may provide a communication bus using a serial bus standard such as Controller Area Network (CAN), Universal Serial Bus (USB), Peripheral Component Interconnect Express (PCIe), and DisplayPort. Devices 26 and 28 connected to the test fixture may transmit and receive data across the bus to the test and measurement instrument 10 or other devices connected to the test fixture 14. While the configuration may include the text fixture 14, it could also be replaced with probes. In some embodiments the text fixture 14 may take the form of a USB hub, as will be discussed in more detail later. The setup may have other variations for different protocols.

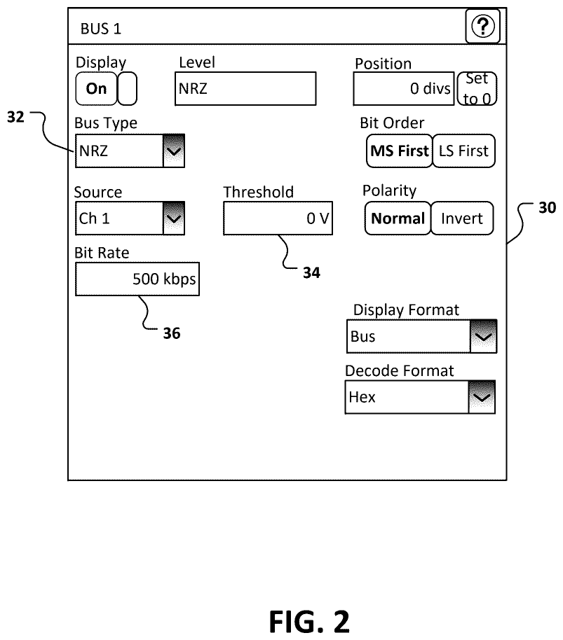

FIG. 2 shows a current example of a user interface on a test and measurement instrument. In the user interface, buttons with boldface text indicate that those buttons have been selected, such as the display selected as “ON” and the Bit Order as “MS First” and the Polarity as “Normal.” In this example, the bus type is selected at 32 as being NRZ. This is a user selection, and the down arrow allows the user to select from a list of bus types. In this user interface, the user must enter the Threshold at 34 and the bit rate, or data rate, at 36.

As mentioned above, when using a conventional test and measurement instrument, the user determines these values by studying and measuring the signal, which may result in inaccurate entries if the signal has a lot of noise or low amplitudes for peak to peak measurements. Setting the data rate and threshold becomes difficult and may result in inaccurate decoding results. Further, in some protocols, like near field communications (NFC), the configuration values change with every acquisition. A user running the test continuously has to perform a single acquisition to set these parameters manually and then repeat for every acquisition.

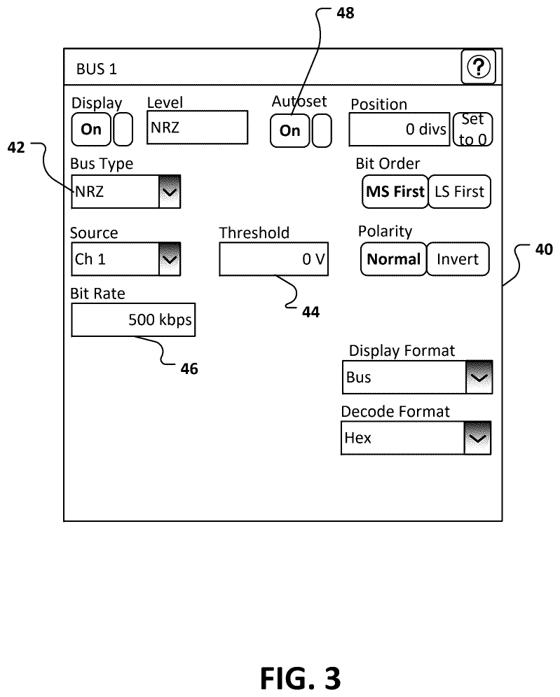

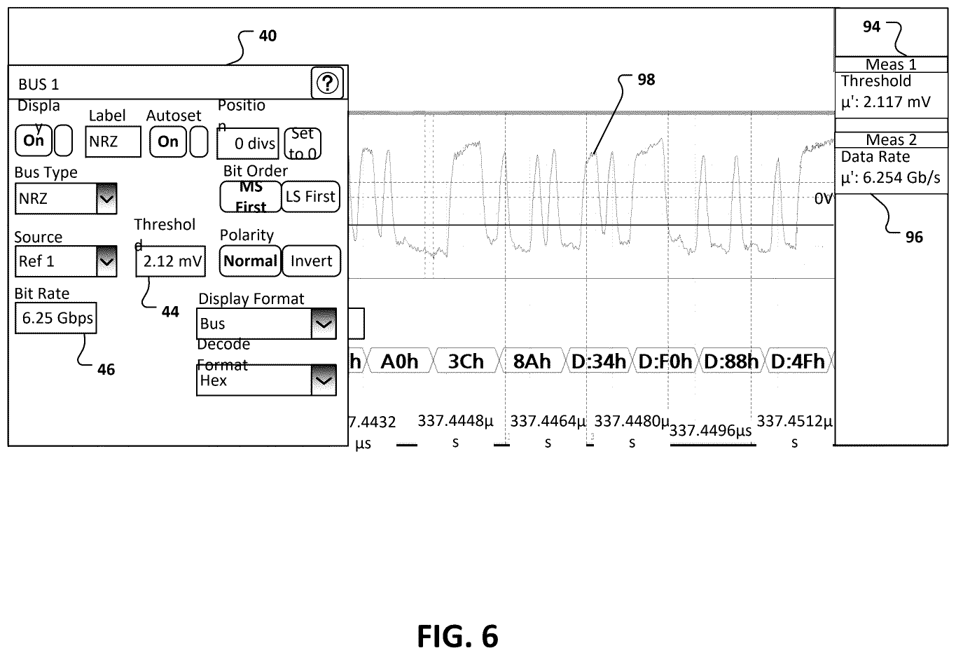

FIG. 3 shows a user interface 40 that provides the user with the option to autoset the values at 48. The user designates the bus type at 42. One or more processors on the test and measurement instrument in FIG. 1 then execute code to analyze the data signal on the bus to determine the threshold and will display that value to the user at 44. The one or more processors will also determine the data rate and display that value to the user in 46 on the user interface. The one or more processors will use these values to decode the data on the bus, discussed in more detail regarding FIG. 6.

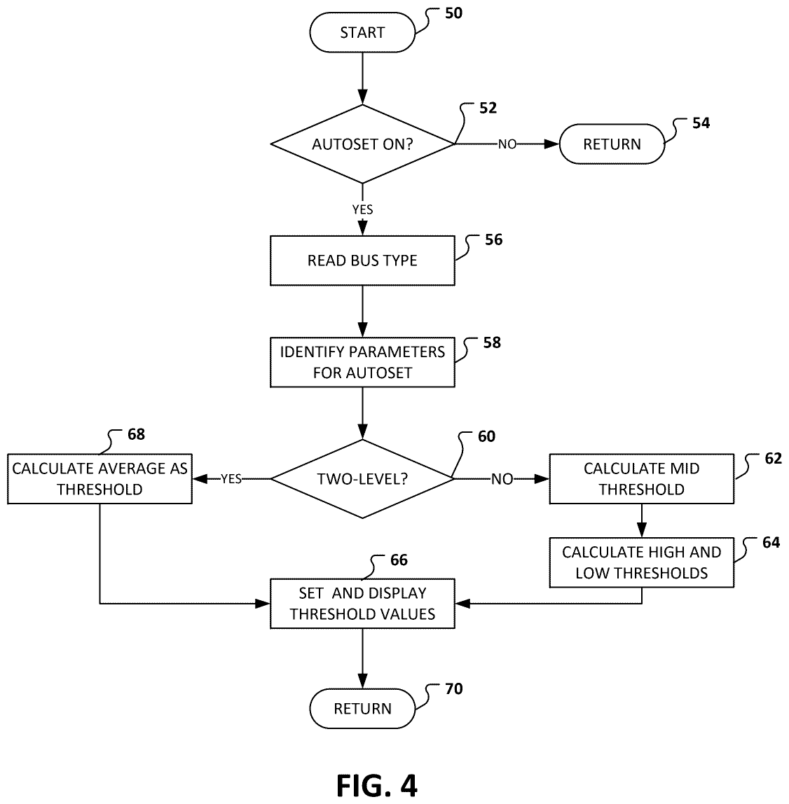

FIG. 4 shows a flowchart of an embodiment of determination of the voltage thresholds from the signal analysis. The process begins at 50, and the test and measurement instrument checks the user inputs to determine if Autoset is on at 52. If Autoset is not on, the process ends and the user would then proceed to perform the test manually. As will be seen in FIG. 6, the instrument may display the user interface 40 from FIG. 3 simultaneously with the decode results. This allows the user to change the setting as needed.

If Autoset is on at 52, the process then checks the bus type selected by the user at 56. The process then uses the bus type to identify the parameters to be determined at 58. In this case the parameter to be determined comprises the threshold. The process then determines if the threshold needed has two levels at 60. A NO answer indicates that the signal has more than two levels, the process continues to calculate a mid threshold based upon the peak to peak values at 62. This process then calculates the low and high thresholds at 64. In one embodiment, the high level results from taking an average of all the upper peaks from the mid threshold, and the low level results from taking an average of all the lower peaks from the mid level. These two levels are then displayed on the user interface and used to decode the traffic. If the answer to the question at 60 is that there are two levels, the average between the highs and lows is taken as the threshold at 68.

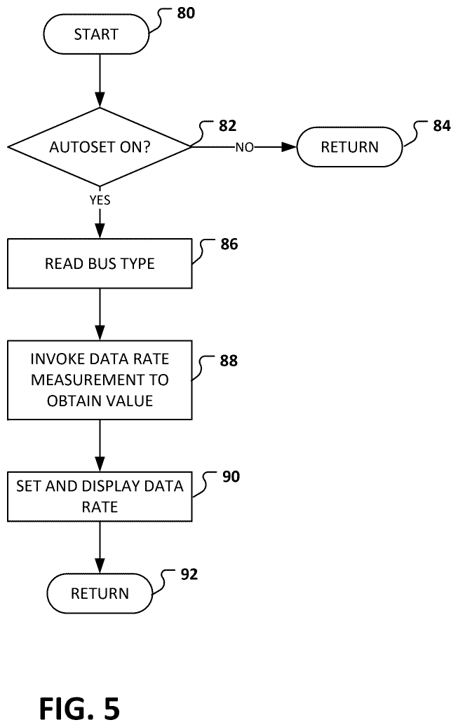

FIG. 5 shows a flowchart of an embodiment of determination of the data rate. The process begins at 80. As in the previous example, the process checks for Autoset being ON at 82, and if not the process returns and ends at 84. If Autoset is on at 82, the bus type input is read at 86. The data rate measurement process then occurs at 88 to determine the data rate of the data traffic on the bus. In one embodiment, the process uses edges from the waveform to calculate the unit time interval (UI) by calculating the numbers of bits between edges. The unit interval gives the Data rate as 1/UI. The process then displays the data rate in the user interface and uses it to decode the data on the bus at 92.

In both FIGS. 4 and 5, the returns at 70 and 92, respectively, could return to iterate the process as needed. As mentioned above, some protocols require parameters to be entered for each acquisition. The iterations would allow the user to just let the instrument determine the parameters as needed for each acquisition avoiding the manual process.

FIG. 6 shows an embodiment of a portion of a test and measurement instrument user interface. The user interface 40 shown in FIG. 3 is replicated on the screen of the user interface and shows the Threshold value as 2.12 mV at 44, and the data rate as 6.25 Gbps at 46. This is shown in boxes 94 and 96. The decoded signal is displayed as 98.

In this manner, the user can perform more accurate decoding of bus data traffic without having to manually determine and enter the values. This results in more accurate decoding and saves the users from having to make the threshold calculations manually.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a test and measurement instrument, comprising: one or more ports to connect one or more devices under test (DUTs) through a bus to one or more channels of the test and measurement instrument; a user interface to allow a user to provide user inputs to the test and measurement instrument; a display to allow a user to view information about the one or more DUTs; one or more processors configured to execute code that causes the one or more processors to: receive a signal from one DUT of the one or more DUTs and convert the signal to a waveform; receive a user input indicating a bus type; use the bus type to identify parameters for autoset detection; autoset one or more parameter values for the bus; decode the waveform using the parameter values to produce decoded results; and display the decoded results on the user interface.

Example 2 is the test and measurement instrument of Example 1, wherein the code that causes the one or more processors to autoset the one or more parameter values comprises code that causes the one or more processors to measure a data rate on the bus and autoset the data rate.

Example 3 is the test and measurement instrument of Example 2, wherein the code that causes the one or more processors to measure the data rate comprises code that causes the one or more processors to: use edges in the waveform to determine a unit interval; and use the inverse of the unit interval to determine the data rate.

Example 4 is the test and measurement instrument of Example 2, wherein the code that causes the one or more processors to autoset the data rate comprises code to cause the one or more processors to set the data rate on a data rate values field on the user interface and use the data rate to decode the waveform.

Example 5 is the test and measurement instrument of any of Examples 1 through 4, wherein the code that causes the one or more processors to autoset one or more parameter values comprise code to cause the one or more processors to autoset a threshold.

Example 6 is the test and measurement instrument of Example 5, wherein the code that causes the one or more processors to autoset the threshold causes the one or more processors to: calculate an average of peak to peak voltages by iterating through all edges in the waveform; and take an average of the peak to peak voltages to determine the threshold when the bus type has one threshold.

Example 7 is the test and measurement instrument of Example 5, wherein the code that causes the one or more processors to autoset the threshold causes the one or more processors to: calculate a mid threshold using a peak to peak voltage measurement in the waveform; determine a high threshold by calculating taking an average of upper peaks from the mid threshold; determine a low threshold by calculating an average of lower peaks from the mid threshold when the bus type has two thresholds.

Example 8 is the test and measurement instrument of any of Examples 1 through 7, wherein the one or more processors are further configured to continuously update the parameter values.

Example 9 is the test and measurement instrument of any of Examples 1 through 8, wherein the one or more processors are further configured to repeat autosetting one or more parameter values for the bus, decoding the waveform using the parameter values to produce decoded result, and displaying the decoded results on the user interface, for a plurality of waveforms after each waveform is acquired.

Example 10 is a method, comprising: receiving a signal from one DUT of one or more DUTs and converting the signal as a waveform; receiving a user input indicating a bus type; using the bus type to identify parameters for autoset detection; autosetting one or more parameter values for the bus; decoding the waveform using the one or more parameter values to produce decoded results; and displaying the decoded results on the user interface.

Example 11 is the method of Example 10, wherein using the bus type to identify parameters comprises measuring the data rate on the bus.

Example 12 is the method of either of Examples 11 or 12, wherein measuring the data rate on the bus comprises: using edges in the waveform to determine a unit interval; and using the inverse of the unit interval to determine the data rate.

Example 13 is the method of any of Examples 10 through 12, wherein autosetting one or more parameters values comprises setting the data rate on a data rate values field on the user interface.

Example 14 is the method of any of Examples 10 through 13, wherein autosetting one or more parameter values comprises autosetting a threshold.

Example 15 is the method of Example 14, wherein autosetting the threshold comprises: calculating an average of peak to peak voltages in the waveform by iterating through all edges in the waveform; and taking an average of the peak to peak voltages to set determine the threshold when the bus type has one threshold.

Example 16 is the method of Example 14, wherein autosetting the threshold comprises: calculating a mid threshold using a peak to peak voltage measurement; determining a high threshold by calculating taking an average of upper peaks from the mid threshold; and determining a low threshold by calculating an average of lower peaks from the mid threshold when the bus type has two thresholds.

Example 17 is the method of any of Examples 10 through 16, further comprising continuously updating the one or more parameter values.

Example 18 is the method of any of Examples 10 through 17, further comprising repeating the autosetting, decoding, and displaying steps, for a plurality of waveforms, after each waveform is acquired.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
one or more ports to connect one or more devices under test (DUTs) through a bus to one or more channels of the test and measurement instrument;
a user interface to allow a user to provide user inputs to the test and measurement instrument;
a display to allow a user to view information about the one or more DUTs;
one or more processors configured to execute code that causes the one or more processors to:
receive a signal from one DUT of the one or more DUTs and convert the signal to a waveform;
receive a user input indicating a bus type;
use the bus type to identify parameters for autoset detection;
autoset one or more parameter values for the bus;
decode the waveform using the parameter values to produce decoded results; and
display the decoded results on the user interface.

2. The test and measurement instrument as claimed in claim 1, wherein the code that causes the one or more processors to autoset the one or more parameter values comprises code that causes the one or more processors to measure a data rate on the bus and autoset the data rate.

3. The test and measurement instrument as claimed in claim 2, wherein the code that causes the one or more processors to measure the data rate comprises code that causes the one or more processors to:
use edges in the waveform to determine a unit interval; and
use the inverse of the unit interval to determine the data rate.

4. The test and measurement instrument as claimed in claim 2, wherein the code that causes the one or more processors to autoset the data rate comprises code to cause the one or more processors to set the data rate on a data rate values field on the user interface and use the data rate to decode the waveform.

5. The test and measurement instrument as claimed in claim 1, wherein the code that causes the one or more processors to autoset one or more parameter values comprise code to cause the one or more processors to autoset a threshold.

6. The test and measurement instrument as claimed in claim 5, wherein the code that causes the one or more processors to autoset the threshold causes the one or more processors to:
calculate an average of peak to peak voltages by iterating through all edges in the waveform; and
take an average of the peak to peak voltages to determine the threshold when the bus type has one threshold.

7. The test and measurement instrument as claimed in claim 5, wherein the code that causes the one or more processors to autoset the threshold causes the one or more processors to:
calculate a mid threshold using a peak to peak voltage measurement in the waveform;
determine a high threshold by calculating taking an average of upper peaks from the mid threshold;
determine a low threshold by calculating an average of lower peaks from the mid threshold when the bus type has two thresholds.

8. The test and measurement instrument as claimed in claim 1, wherein the one or more processors are further configured to continuously update the parameter values.

9. The test and measurement instrument as claimed in claim 1, wherein the one or more processors are further configured to repeat autosetting one or more parameter values for the bus, decoding the waveform using the parameter values to produce decoded result, and displaying the decoded results on the user interface, for a plurality of waveforms after each waveform is acquired.

10. A method, comprising:
receiving a signal from one DUT of one or more DUTs and converting the signal as a waveform;
receiving a user input indicating a bus type;
using the bus type to identify parameters for autoset detection;
autosetting one or more parameter values for the bus;
decoding the waveform using the one or more parameter values to produce decoded results; and
displaying the decoded results on the user interface.

11. The method as claimed in claim 10, wherein using the bus type to identify parameters comprises measuring the data rate on the bus.

12. The method as claimed in claim 11, wherein measuring the data rate on the bus comprises:
using edges in the waveform to determine a unit interval; and
using the inverse of the unit interval to determine the data rate.

13. The method as claimed in claim 10, wherein autosetting one or more parameters values comprises setting the data rate on a data rate values field on the user interface.

14. The method as claimed in claim 10, wherein autosetting one or more parameter values comprises autosetting a threshold.

15. The method as claimed in claim 14, wherein autosetting the threshold comprises:
calculating an average of peak to peak voltages in the waveform by iterating through all edges in the waveform; and
taking an average of the peak to peak voltages to set determine the threshold when the bus type has one threshold.

16. The method as claimed in claim 14, wherein autosetting the threshold comprises:
calculating a mid threshold using a peak to peak voltage measurement;
determining a high threshold by calculating taking an average of upper peaks from the mid threshold; and
determining a low threshold by calculating an average of lower peaks from the mid threshold when the bus type has two thresholds.

17. The method as claimed in claim 10, further comprising continuously updating the one or more parameter values.

18. The method as claimed in claim 10, further comprising repeating the autosetting, decoding, and displaying steps, for a plurality of waveforms, after each waveform is acquired.
